(19) United States
(12) Patent Application Publication
(10) Pub. No.: US 2014/0000674 A1
(43) Pub. Date: Jan. 2, 2014

(54) PHOTOVOLTAIC MODULE BACK-SHEET AND PROCESS OF MANUFACTURE

(71) Applicant: E I DU PONT DE NEMOURS AND COMPANY, Wilmington, DE (US)

(72) Inventor: CHEN QIAN ZHAO, Newark, DE (US)

(73) Assignee: E I DU PONT DE NEMOURS AND COMPANY, Wilmington, DE (US)

(21) Appl. No.: 13/792,723

(22) Filed: Mar. 11, 2013

Related U.S. Application Data
(60) Provisional application No. 61/664,872, filed on Jun. 27, 2012.

(51) Int. Cl. H01L 31/048

(52) U.S. Cl. CPC H01L 31/0487; H01L 31/0481
USPC 136/244; 428/421; 427/207.1; 438/73

(57) ABSTRACT

An integrated back-sheet for a photovoltaic module is provided. A process for forming the back-sheet includes the steps of providing a fluoropolymer film, providing a polymer melt comprising 10 to 85 weight percent olefin-based elastomer, 5 to 75 weight percent of inorganic particulates, and 5 to 80 weight percent of adhesive selected from thermoplastic polymer adhesives and tackifiers, and depositing the polymer melt directly on the fluoropolymer film to form a polymer layer with a surface adhered directly to the fluoropolymer film. When incorporated into a photovoltaic module, the polymer layer of the back-sheet is adhered directly to the rear surfaces of a plurality of solar cells.

### CLAIM OF PRIORITY

This application claims priority from the following U.S. Provisional Application, which is hereby incorporated by reference: Photovoltaic Module Back-Sheet and Process of Manufacture, Application Ser. No. 61/664,872, filed 27 Jun. 2012 (PV0027).

### BACKGROUND OF THE INVENTION

1. Field of the Disclosure

The present invention relates to durable protective films and sheets for photovoltaic modules, and more particularly to an integrated photovoltaic module back-sheet comprising an olefin-based elastomer layer adhered directly to a fluoropolymer film. The invention also relates to a process for manufacturing an integrated back-sheet for photovoltaic modules in which a layer of an olefin-based elastomer is melt deposited directly on and adhered to a fluoropolymer film, and to a process for adhering such an integrated back-sheet directly to the back side of photovoltaic cells to produce a photovoltaic module with an integrated back-sheet.

2. Description of the Related Art

A photovoltaic module (also know as a solar cell module) refers to a photovoltaic device for generating electricity directly from light, particularly, from sunlight. Typically, an array of individual solar cells is electrically interconnected and assembled in a module, and an array of modules is electrically interconnected together in a single installation to provide a desired amount of electricity. If the light absorbing semiconductor material in each cell, and the electrical components used to transfer the electrical energy produced by the cells, can be suitably protected from the environment, photovoltaic modules can last 20, 30, and even 40 or more years without significant degradation in performance.

As shown in FIG. 1, a conventional photovoltaic module 10 is shown in cross section with a light-transmitting substrate 12 or front sheet, an encapsulant layer 14, an active photovoltaic cell layer 16, another encapsulant layer 18 and a protective back-sheet 20. The light-transmitting front sheet substrate, also known as the incident layer, is typically glass or a durable light-transmitting polymer film. The encapsulant layers 14 and 18 adhere the photovoltaic cell layer 16 to the front and back sheets, they seal and protect the photovoltaic cells from moisture and air, and they protect the photovoltaic cells against mechanical impacts such as hail. The encapsulant layers 14 and 18 are typically comprised of a thermoplastic or thermosetting resin such as ethylene-vinyl acetate copolymer (EVA). The photovoltaic cell layer 16 may be any type of solar cell that converts sunlight to electric current such as single crystal silicon solar cells, polycrystalline silicon solar cells, microcrystalline silicon solar cells, amorphous silicon-based solar cells, copper indium (gallium) diselenide solar cells, cadmium telluride solar cells, compound semiconductor solar cells, dye sensitized solar cells, and the like. The back-sheet 20 provides structural support for the module 10, it electrically insulates the module, and it helps to protect the module wiring and other components against the elements, including heat, water vapor, oxygen and UV radiation. The back-sheet needs to remain intact and adhered to the rest of the module for the service life of the photovoltaic module, which may extend for multiple decades.

Multilayer laminates have been employed as photovoltaic module back-sheets. One or more of the laminate layers in such back-sheets conventionally comprise a highly durable and long lasting polyvinyl fluoride (PVF) film which is available from E. I. du Pont de Nemours and Company as Tedlar® film. PVF films resist degradation by sunlight and they provide a good moisture barrier properties over long periods of time. PVF films are typically laminated to other polymer films that contribute mechanical and dielectric strength to the back-sheet, such as polyester films, as for example polyethylene terephthalate (PET) films. Back-sheets of PVF/PET or of PVF/PET/PVF are adhered to the encapsulant layer on the back side of the solar cells.

There is a need for a photovoltaic module back-sheet that is durable over extended periods of time, that can adhere directly to the back surface of solar cells so as to seal and protect the solar cells, and that offers excellent moisture resistance and good electrical insulation properties. There is a further need for such photovoltaic module back-sheets and modules that are economical to produce and use.

### SUMMARY

The invention provides a process for forming a back-sheet for a photovoltaic module. The disclosed process includes the steps of:

providing a fluoropolymer film;

providing a polymer melt comprising 10 to 85 weight percent olefin-based elastomer, 5 to 75 weight percent of inorganic particulates, and 5 to 80 weight percent of adhesive selected from thermoplastic polymer adhesives and tackifiers, based on the weight of the polymer melt, wherein the olefin-based elastomer is a copolymer comprised of at least 50 wt % of monomer units selected from ethylene and propylene monomer units copolymerized with one or more different C₂₋₂₀ alpha olefin monomer units, and said olefin-based elastomer has a melt index of less than 25 g/10 minutes measured according to ASTM D1238;

depositing the polymer melt directly on the fluoropolymer film and pressing the fluoropolymer film and polymer melt together and cooling the polymer melt to form a first polymer layer from the polymer melt, the first polymer layer having a thickness of at least 0.1 mm, wherein the peel strength between said fluoropolymer film and said first polymer layer is greater than 2 Newtons/cm after 1000 hours of exposure at 85° C. and 85% relative humidity.

In one preferred embodiment, the polymer layer comprises 20 to 75 weight percent olefin-based elastomer, 10 to 70 weight percent of inorganic particulates, and 10 to 60 weight percent of adhesive selected from thermoplastic polymer adhesives and rosin based tackifiers, based on the weight of the first polymer layer.

The adhesive is preferably a non-aromatic copolymer comprised of ethylene units copolymerized with one or more of the monomer units selected from C₃₋₂₀ alpha olefins, C₁₋₄ alkyl methacrylates, C₁₋₄ alkyl acrylates, methacrylic acid, acrylic acid, maleic anhydride, and glycidyl methacrylate, wherein the adhesive copolymer is comprised of at least 50 wt % ethylene derived units. The inorganic particulates preferably comprise silica, silicates, calcium carbonate and titanium dioxide particles having an average particle diameter in the range of 0.1 to 100 microns.

The polymer melt may be deposited on the fluoropolymer film by extruding the polymer melt as a layer directly onto the fluoropolymer film or by calendar melting and coating the polymer melt onto the fluoropolymer film. The polymer layer preferably has a thickness of at least 0.1 mm and a peel strength between said fluoropolymer film and said first polymer layer after 1000 hours of exposure at 85° C. and 85% relative humidity that is greater than 2 Newtons/cm, and more preferably greater than 8 Newtons/cm.

A process for forming a photovoltaic module is also provided wherein the above described polymer melt is deposited directly on the fluoropolymer film to form a first polymer layer and a side of the first polymer layer is disposed directly against the rear side of solar cells and heated to adhere the first polymer layer to the rear side of the solar cells.

An integrated back-sheet for a photovoltaic module having the composition discussed above is also provided. A photovoltaic module in which the olefin-based elastomer layer of the integrated back-sheet is adhered directly to the rear side of a plurality of solar cells of the module is also provided in which the fluoropolymer film forms an exposed surface of the photovoltaic module.

### BRIEF DESCRIPTION OF THE DRAWINGS

The detailed description will refer to the following drawings, wherein like numerals refer to like elements:

FIG. 1 is a cross-sectional view of a conventional photovoltaic module;

FIG. 2 is a schematic view of a process for producing a back-sheet according to one disclosed process;

FIG. 3 is a schematic view of a process for producing a back-sheet according to another disclosed process;

FIG. 4 is a schematic view of a process for producing a back-sheet according to another disclosed process;

FIG. 5 is a cross-sectional view of a photovoltaic module with a disclosed integrated back-sheet.

### DETAILED DESCRIPTION

To the extent permitted by the United States law, all publications, patent applications, patents, and other references mentioned herein are incorporated by reference in their entirety.

The materials, methods, and examples herein are illustrative only and the scope of the present invention should be judged only by the claims.

### Definitions

The following definitions are used herein to further define and describe the disclosure.

The terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The terms “a” and “an” include the concepts of “at least one” and “one or more than one”.

Unless stated otherwise, all percentages, parts, ratios, etc., are by weight.

When the term “about” is used in describing a value or an end-point of a range, the disclosure should be understood to include the specific value or end-point referred to.

The terms “sheet”, “layer” and “film” are used in their broad sense interchangeably. A “back-sheet” is a sheet, layer or film on the side of a photovoltaic module that faces away from a light source, and is generally opaque.

“Encapsulant” means material used to encase the fragile voltage-generating solar cell layer to protect it from environmental or physical damage and hold it in place in a photovoltaic module. Encapsulant layers are conventionally positioned between the solar cell layer and the incident front sheet layer, and between the solar cell layer and the back-sheet backing layer. Suitable polymer materials for these encapsulant layers typically possess a combination of characteristics such as high transparency, high impact resistance, high penetration resistance, high moisture resistance, good ultraviolet (UV) light resistance, good long term thermal stability, adequate adhesion strength to front-sheets, back-sheets, other rigid polymeric sheets and solar cell surfaces, and long term weatherability.

The term “copolymer” is used herein to refer to polymers containing copolymerized units of two different monomers (a dipolymer), or more than two different monomers.

Durable substrates for use as back-sheets in photovoltaic modules are disclosed. Photovoltaic modules made with such durable substrates as the module back-sheet are also disclosed. Also disclosed are processes for making such durable back-sheet, and processes for making photovoltaic modules with the durable substrates as the back-sheet. The disclosed durable substrate is a layer of an electrically insulating olefin-based elastomer that is adhered directly to a thermoplastic fluoropolymer film, such as a polyvinyl fluoride (PVF) homopolymer or copolymer film or a polyvinyl idene (PVDF) homopolymer or copolymer film. The olefin-based elastomer layer includes inorganic particulate and a thermoplastic adhesive or a tackifier.

The disclosed integrated back-sheet comprises an electrically insulating polymer layer comprised of an olefin-based elastomer, inorganic particulate material, and a thermoplastic adhesive or a tackifier. The olefin-based elastomer, inorganic particulates, and thermoplastic polymer adhesive or tackifier are adhered to a fluoropolymer layer such as a PVF or PVDF film. In one aspect, the olefin-based elastomer containing layer comprises 10 to 85% by weight of olefin-based elastomer, 5 to 75% by weight of inorganic particulate material, and 5 to 80% by weight of one or more of thermoplastic polymer adhesive or tackifier, based on the total weight of the olefin-based elastomer containing layer, and more preferably 20 to 75% by weight of olefin-based elastomer, 10 to 70% by weight of inorganic particulate material, and 10 to 60% by weight of one or more of thermoplastic polymer adhesive and tackifier. Most preferably, the olefin-based elastomer containing layer is comprised of 25 to 65% by weight of olefin-based elastomer, 25 to 60% by weight of inorganic particulate material, and 10 to 30% by weight of one or more of a thermoplastic polymer adhesive and a tackifier.

As used herein “olefin-based elastomer” means a copolymer comprised of at least 50 wt % of ethylene and/or propylene derived units copolymerized with a different alpha olefin monomer unit selected from C₂₋₂₀ alpha olefins. Preferred olefin-based elastomers are of high molecular weight with a melt index of less than 25 g/10 min, and more preferably less than 15 g/10 min, and even more preferably less than 10 g/10 min based on ASTM D1238. The preferred olefin-based elastomers are polymerized using constrained geometry catalysts such as metallocene catalysts. The preferred olefin-based elastomers provide excellent electrical insulation, good long term chemical stability, as well as high strength, toughness and elasticity. A preferred olefin-based elastomer is comprised of more than 70 wt % propylene derived units copolymerized with comonomer units derived from ethylene or C₄₋₂₀ alpha olefins, for example, ethylene, 1-butene, 1-hexane, 4-methyl-1-pentene and/or 1-octene. A preferred propylene-based elastomer is a semicrystalline copolymer of propylene units copolymerized with ethylene units using constrained geometry catalysts, having a melt index of less than 10 g/10 min (ASTM D1238), that can be obtained from ExxonMobil Chemical of Houston, Tex., under the product names “Vistamaxx™ 6102” and “Vistamaxx™ 6202”. Such propylene-based elastomers are generally described in U.S. Pat. No. 7,863,206. Another preferred olefin-based elastomer is comprised more than 70 wt % ethylene derived units copolymerized with comonomer units derived from C₃₋₂₀ alpha olefins, for example, 1-propene, isobutylene, 1-butene, 1-hexane, 4-methyl-1-pentene and/or 1-octene. A preferred ethylene-based elastomer is a flexible and elastic copolymer comprised of ethylene units copolymerized with alpha olefin units using constrained geometry catalysts, having a melt index of 5 g/10 min (ASTM D1238; 190° C./2.16 Kg), that can be obtained from the Dow Chemical Company of Midland, Mich. under the product name Affinity™ EG8200G. Such ethylene-based elastomers are generally described in U.S. Pat. Nos. 5,272,236 and 5,278,236.

The electrically insulating olefin-based elastomer containing layer further comprises 5% to 75% by weight of inorganic particulates (based on the weight of the layer), and more preferably 10% to 70% by weight of inorganic particulates, and even more preferably 25% to 60% by weight of inorganic particulates. The inorganic particulates may comprise amorphous silica or silicates such as crystallized mineral silicates. Preferred silicates include clay, kaolin, wollastinite, vermiculite, mica and talc (magnesium silicate hydroxide). The inorganic particulate materials may also comprise one or more of calcium carbonate, alumina trihydrate, antimony oxide, magnesium hydroxide, barium sulfate, alumina, titania, titanium dioxide, zinc oxide and boron nitride. Preferred inorganic particulate materials have an average particle diameter less than 100 microns, and preferably less than 45 microns, and more preferably less than 15 microns. If the particle size is too large, defects, voids, pin holes, and surface roughness of the film may be a problem. If the particle size is too small, the particles may be difficult to disperse and the viscosity may be excessively high. Average particle diameters of the inorganic particulates are preferably between and including any two of the following diameters: 0.1, 0.2, 1, 15, 45 and 100 microns. More preferably, the particle diameter of more than 99% of the inorganic particulates is between 0.1 and 45 microns, and more preferably between about 0.2 and 15 microns.

The inorganic particulate material adds reinforcement and mechanical strength to the sheet and it reduces sheet shrinkage and curl. Platelet shaped particulates such as mica and talc and/or fibrous particles provide especially good reinforcement. The inorganic particulates also improve heat dissipation from the solar cells to which the integrated back-sheet is attached which reduces the occurrence of hot spots in the solar cells. The presence of the inorganic particulates also improves the fire resistance of the back-sheet. The inorganic particulates also contribute to the electrical insulation properties of the back-sheet. The inorganic particulates may also be selected to increase light refractivity of the back-sheet which serves to increase solar module efficiency and increase the UV resistance of the back-sheet. Inorganic particulate pigments such as titanium dioxide make the sheet whiter, more opaque and more reflective which is often desirable in a photovoltaic module back-sheet layer. The presence of the inorganic particulates can also serve to reduce the overall cost of the olefin-based elastomer containing layer.

The olefin-based elastomer containing substrate layer further comprises one or more thermoplastic polymer adhesives or tackifiers. The adhesive or tackifier makes it possible for the olefin-based elastomer containing substrate layer to adhere directly to the fluoropolymer film without the use of an additional adhesive layer. The thermoplastic polymer adhesives and/or tackifiers serve to improve the adhesion of the olefin-based elastomer substrate to the fluoropolymer outer layer of the integrated back-sheet such as a PVF or PVDF film. The thermoplastic adhesive or tackifier may also serve to improve the adhesion of the integrated back-sheet to the back of the solar cells when the olefin-based elastomer containing layer of the integrated back-sheet is adhered to the back of the solar cells.

A preferred thermoplastic adhesive is a polyolefin plastomer such as a non-aromatic ethylene-based copolymer adhesive plastomer of low molecular weight with a melt flow index of greater than 250. Such polyolefin adhesive materials are highly compatible with the olefin-based elastomer, they have low crystallinity, they are non-corrosive, and they provide good adhesion to fluoropolymer films. A preferred polyolefin plastomer is Affinity™ GA 1950 polyolefin plastomer obtained from Dow Chemical Company of Midland, Mich. Other thermoplastic polymer adhesives useful in the disclosed olefin-based elastomer containing back-sheet substrate include ethylene copolymer adhesives such as ethylene acrylic acid copolymers and ethylene acrylate and methacrylate copolymers. Ethylene copolymer adhesives that may be used as the thermoplastic adhesive include copolymers comprised of at least 50 wt % ethylene monomer units, copolymerized in one or more of the following: ethylene-C₁₋₄ alkyl methacrylate copolymers and ethylene-C₁₋₄ alkyl acrylate copolymers; ethylene-methacrylic acid copolymers, ethylene-acrylic acid copolymers, and blends thereof; ethylene-maleic anhydride copolymers; polybasic polymers formed of ethylene monomer units with at least two co-monomers selected from C₁₋₄ alkyl methacrylate, C₁₋₄ alkyl acrylate, ethylene-methacrylic acid, ethylene-acrylic acid and ethylene-maleic anhydride; copolymers formed by ethylene and glycidyl methacrylate with at least one co-monomer selected from C₁₋₄ alkyl methacrylate, C₁₋₄ alkyl acrylate, ethylene-methacrylic acid, ethylene-acrylic acid, and ethylene-maleic anhydride; and blends of two or more of these ethylene copolymers. Another thermoplastic adhesive useful in the olefin-based elastomer containing substrate layer of the disclosed integrated back-sheet is an acrylic hot melt adhesive. Such an acrylic hot melt adhesive may serve as the thermoplastic adhesive on its own or in conjunction with an ethylene copolymer adhesive to improve the adhesion of the olefin-based elastomer layer of the back-sheet to the fluoropolymer film. One preferred acrylic hot melt adhesive is Euromelt 707 US synthetic hot melt adhesive from Henkel Corporation of Dusseldorf, Germany. Other thermoplastic adhesives that may be utilized in the olefin-based elastomer substrate layer include polyurethanes, synthetic rubber, and other synthetic polymer adhesives.

Preferred tackifiers useful in the disclosed olefin-based elastomer containing layer of the back-sheet include hydrogenated rosin-based tackifiers, acrylic low molecular weight tackifiers, synthetic rubber tackifiers, hydrogenated polyolefin tackifiers such as polyterpene, and hydrogenated aromatic hydrocarbon tackifiers. Two preferred hydrogenated rosin-based tackifiers include FloraRez 485 glycerol ester hydrogenated rosin tackifier from Florachem Corporation and Stabelite Ester-E hydrogenated rosin-based tackifier from Eastman Chemical.

The olefin-based elastomer substrate layer may further comprise additives including, but are not limited to, plasticizers such as polyethylene glycol, processing aides, flow enhancing additives, lubricants, dyes, flame retardants, impact modifiers, nucleating agents to increase crystallinity, antiblocking agents such as silica, thermal stabilizers, hindered amine light stabilizers (HALS), UV absorbers, UV stabilizers, antioxidants, dispersants, surfactants, and primers, and additional reinforcement additives, such as glass fiber and the like.

The olefin-based elastomer, the inorganic particulates, and the thermoplastic adhesive or tackifier may be compounded and mixed by methods known in the art. This mixture is melted and melt deposited as a layer directly on a fluoropolymer film. When the integrated back-sheet is applied to a module, the fluoropolymer film layer will be on the side of the olefin-based elastomer containing layer that is opposite from the solar cell layer. The olefin-based elastomer containing layer adheres directly to the fluoropolymer film without the need for an additional adhesive layer.

As used herein “fluoropolymer” means homoplymers and copolymers of fluorinated monomer units and copolymers of fluorinated monomers and non-fluorinated monomers in which the fluorinated monomer units in the copolymer account for 40 to 99% by weight of the copolymer. The fluoropolymer film may, for example, be comprised of polyvinyl fluoride, polyvinylidene fluoride, polytetrafluoroethylene, poly chloro trifluoroethylene, ethylene-tetrafluoroethylene copolymers, tetrafluoroethylene/hexafluoropropylene/vinylidene fluoride terpolymer (THV), copolymers and terpolymers comprising polyvinyl fluoride and polytetrafluoroethylene, and the like. Preferred fluoropolymer films include PVF homopolymer or copolymer film or PVDF homopolymer or copolymer film. Suitable PVF films are more fully disclosed in U.S. Pat. No. 6,632,518.

The thickness of the fluoropolymer film layer is not critical and may be varied depending on the particular application. Generally, the thickness of the fluoropolymer film will range from about 0.1 to about 10 mils (about 0.003 to about 0.26 mm), and more preferably within the range of about 1 mil (0.025 mm) to about 4 mils (0.1 mm).

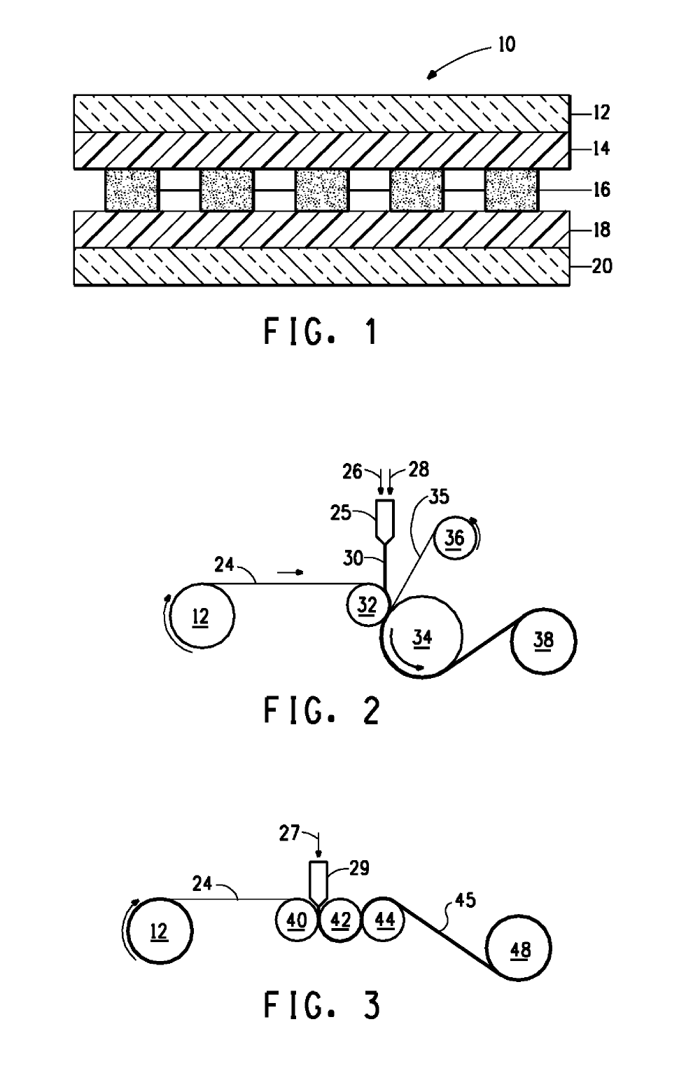

One process for forming the disclosed solar panel back-sheet material is illustrated in FIG. 2. A fluoropolymer film 24 is fed from a roll 12 to an extrusion coating station comprising a single screw or twin screw extruder and an extrusion die. An olefin-based elastomer containing melt layer 30 is extruded from an extruder die 25. The extruded olefin-based elastomer containing layer 30 may be comprised of a single olefin-based elastomer containing layer or of multiple co-extruded layers where each layer is designed to perform a specific function. For example, and as shown in FIG. 1, one or more different olefin-based elastomer containing feeds 26 and/or 28 are fed to the extruder where the feed 26 forms an olefin-based elastomer containing melt layer formulated to adhere to the fluoropolymer film, and where the feed 28 forms a distinct olefin-based elastomer containing sub-layer with properties that will allow it to adhere well to the back of a photovoltaic module when the back-sheet laminate is adhered directly to the back side of solar cells during vacuum lamination of the module. For example, a tackifier or a thermoplastic polymer adhesive, such as a functionalized ethylene copolymer, can be added to one or more of the layers to make them adhere well to the fluoropolymer film layer whereas a lower level of adhesive or no adhesive may need to be added for the olefin-based elastomer to adhere well to the back of the solar cells during vacuum lamination. It is contemplated that the extruded olefin-based elastomer containing layer 30 could be made with additional sub-layers that serve other functions such as joining the other sub-layers together or providing desired moisture barrier or electrical insulating properties.

The olefin-based elastomer containing material, which includes olefin-based elastomer, inorganic particulate material, and thermoplastic polymer adhesive or tackifier, is melted in the extruder and extruded through a slit die to form a melt layer 30 that is extrusion coated directly onto the surface of the fluoropolymer film 24. The opening of the die is preferably spaced about 10 to 500 mm from the surface of the fluoropolymer film. The die thickness, the melt extrusion rate and the line speed of the fluoropolymer film are adjusted to obtain an olefin-based elastomer containing layer coating with a thickness of about 0.1 to 1.3 mm, and more preferably with a thickness of about 0.25 to 0.80 mm. The coated film is passed through a nip formed between the rolls 32 and 34. The rolls 32 and 34 are lamination rollers as known in the art, and may have hard or flexible surfaces, and may be heated or cooled depending on the desired processing conditions. The temperature of the rolls 32 and 34 are preferably in the range of 40° to 150° C., and more preferably 50° to 110° C. The roll surfaces may have a gloss or matte finishes. The pressure in the nips formed between the rolls 32 and 34 is preferably in the range of about 30 to 100 psi (21 to 69 N/cm²). An optional release layer 35, such as a Mylar® polyester film, wax release paper, or a silicon release sheet, may be fed into the nip between the olefin-based elastomer containing layer and the lamination roll 34. The olefin-based elastomer containing layer on the fluoropolymer film, with the optional release film 35, is collected on a collection roll 38 after coming off the lamination roller 34.

An alternative process for producing the disclosed integrated back-sheet is schematically illustrated in FIG. 3. The olefin-based elastomer containing material, which includes olefin-based elastomer, inorganic particulate material, and compatible adhesive thermoplastic polymer or tackifier, is melted in the extruder 29 and extruded through a slit die directly into a nip formed between the rolls 40 and 42. A fluoropolymer film 24 is also fed into the nip from a roll 12. The olefin-based elastomer containing melt is formed into a sheet layer by the nip between the roll 40 and 42 and by the nip between the roll 42 and the roll 44 to which the olefin-based elastomer containing layer and the fluoropolymer film are transferred. The sheeting rolls 40, 42 and 44 form the olefin-based elastomer containing layer into a uniformly thick layer adhered to the fluoropolymer film 24. The opening of the die is preferably spaced about 10 to 500 mm from the nip between the rolls 40 and 42. The die thickness, the melt extrusion rate, the line speed, and the nip opening are adjusted to obtain an olefin-based elastomer containing layer coating with a thickness of about 0.1 to 1.3 mm, and more preferably with a thickness of about 0.25 to 0.80 mm. The rolls 40, 42 and 44 are quench/nip rolls as known in the art, and may have hard or flexible surfaces, and may be heated or cooled depending on the desired processing conditions. The temperature of the rolls 40, 42 and 44 are preferably in the range of 40° to 150° C., and more preferably 50° to 110° C. The roll surface may have a gloss or matte finish. The nip pressure is preferably in the range of 30 to 90 psi (207-612 kPa). The olefin-based elastomer/fluoropolymer film laminate 45 is collected on a take-up roll 48. In an alternative embodiment, a release sheet (not shown), as described with regard to the sheet 35 of FIG. 2, is applied over the free surface of the olefin-based elastomer containing layer before the olefin-based elastomer/fluoropolymer film laminate is collected on the collection roll 48.

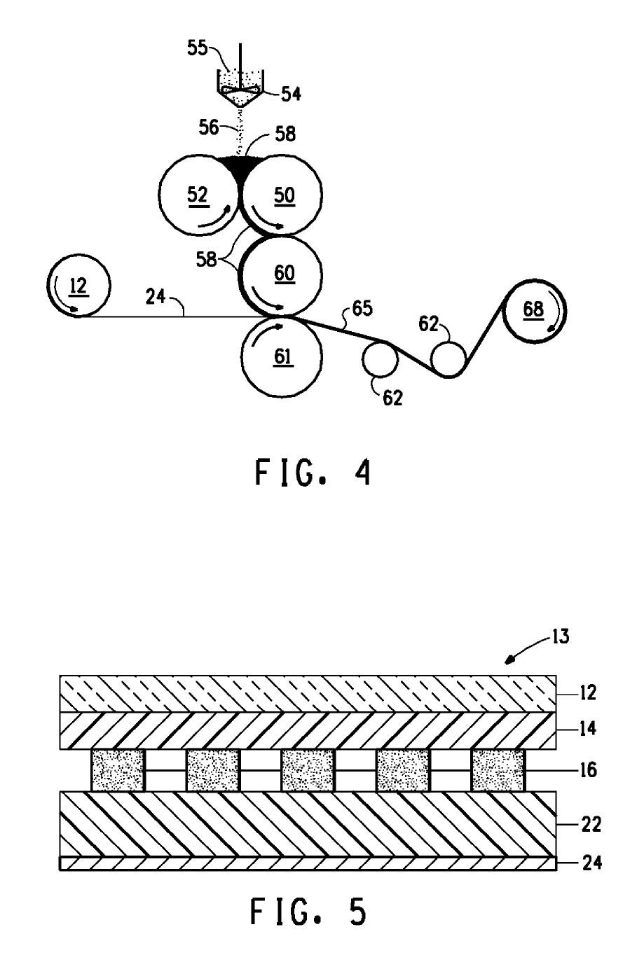

Another alternative process for forming an olefin-based elastomer/fluoropolymer integrated back-sheet laminate is schematically shown in FIG. 4. The olefin-based elastomer, inorganic particulate material, and compatible adhesive thermoplastic polymer or tackifier are mixed in a compounder such a screw compounding machine. The compounded olefin-based elastomer containing mixture is pelletized into pellets 55 and fed into a mixer 54. The pellets are discharged from the mixer 54 as a pellet stream 56 to a melt zone 58 formed between the heated calendar rolls 50 and 52. Preferably the calendar rolls have a chrome plated surface, and are heated to a surface temperature in the range of 40 to 150° C., and more preferably 50 to 110° C. The calendar rolls typically have a diameter of form 20 to 60 cm and a length of from 15 cm to 2 m. The calendar rolls 50 and 52 are spaced from each other by about 0.15 to 1.2 mm, and more preferably by about 0.3 to 0.8 mm, depending upon the desired thickness of the olefin-based elastomer layer. A molten film 58 of the melted olefin-based elastomer containing melt is carried on the surface of the heated calendar roll 50 as shown in FIG. 4. The molten film 58 transfers to an adjoining roll 60 located below the calendar roll 50 and that is rotating in the same direction as the calendar roll 50. The roll 60 has a diameter and length similar to the calendar roll 50, but may be larger or smaller. Roll 60 preferably has a chrome plated surface, and is heated to a surface temperature in the range of 20 to 150° C.

A fluoropolymer film 24 is fed from a supply roll 12 to a nip formed between the roll 60 and a roll 61. The roll 61 presses the fluoropolymer film into contact with the olefin-based elastomer containing material on the surface of the heated calendar roll 60 such that the olefin-based elastomer containing material is transferred to the fluoropolymer film. The nip pressure is preferably in the range of 30 to 90 psi (207-612 kPa). The roll 61 has a diameter and length that is similar to the diameter and length of the roll 60, but may be larger or smaller. The roll 61 preferably has a chrome plated surface with a surface speed that is substantially the same as the surface speed of the roll 60 and the calendar roll 50. The roll 61 is preferably heated to a surface temperature in the range of 100 to 160° C., and more preferably 110 to 150° C. The olefin-based elastomer containing layer/fluoropolymer film laminate 65 is carried by the transfer rollers 62 to a collection roll 68. In one embodiment (not shown), a release sheet, as described above with regard to the sheet 35 of FIG. 2, is applied over the free surface of the olefin-based elastomer containing layer before the olefin-based elastomer containing layer/fluoropolymer film is collected on the collection roll 68.

The olefin-based elastomer, inorganic particulate material, and thermoplastic polymer adhesive or tackifier forms a layer 22 directly on, and strongly adhered to, the fluoropolymer film 24 as can be seen in the photovoltaic module cross-sectional view of FIG. 5. The olefin-based elastomer containing layer preferably has a thickness in the range of 0.1 to 1.3 mm, and more preferably between 0.25 to 0.80 mm. It is important that the olefin-based elastomer containing layer not delaminate from the fluoropolymer film, even after extended exposure to heat and humidity. This must be the case of the integrated back-sheet both before and after the back-sheet is attached to the solar cells of a photovoltaic module by a thermal and/or vacuum lamination process. The peel strength between the fluoropolymer film and the olefin-based elastomer containing layer of the integrated back-sheet, after 1000 hours of exposure to damp heat (85° C. at 85% relative humidity) is preferably at least 2 Newtons/cm, and more preferably at least 8 Newtons/cm, when tested according to ASTM D3167.

The surface of the olefin-based elastomer containing layer opposite to the side on which the olefin-based elastomer containing layer is adhered to the fluoropolymer film adheres directly to the back side of the solar cell layer and no other encapsulant layer is used on the back side of the solar cell. The olefin-based elastomer containing layer serves the functions of both a back-sheet and an encapsulant layer on the back side of the solar cell. That is, the integrated back-sheet electrically insulates the solar cells, it seals and protects the cells against oxygen, moisture and UV radiation, and it cushions and protects the solar cells against physical impacts such as hail. A separate conventional encapsulant layer is still used on the front side of the solar cell. FIG. 5 shows a cross-sectional view of an olefin-based elastomer containing sheet 22 adhered directly to the rear side of the solar cell layer 16. A light transmitting front sheet 12 is adhered to a front encapsulant layer 14 on the front side of the solar cell layer 16. The front sheet 12 is typically a glass or transparent polymer sheet and the encapsulant layer 14 may be a conventional encapsulant such as ethylene vinyl acetate copolymer or ionomer. The olefin-based elastomer containing sheet 22 serves as both the rear encapsulant layer and as a portion of the back-sheet of the photovoltaic module 13. The edges of module 13 between the front encapsulant layer 14 and the olefin-based elastomer containing layer 22 can be sealed with a conventional edge seal such as a polybutyl rubber edge seal material.

In another embodiment, the photovoltaic module with an olefin-based elastomer substrate may have one or more metal layers incorporated on or into the olefin-based elastomer containing layer. The metal layer(s) can be a thin metal foil such as an aluminum, copper or nickel foil, a plated metal layer, a sputtered metal layer or a metal layer deposited by other means such as chemical solution deposition. Preferred metal layers include metal foils, metal oxide layers and sputtered metal layers. Such metal layers provide increased resistance to moisture ingress. Such metal layers can be formed on the surface of the olefin-based elastomer containing layer in the form of circuits that can be electrically connected to the electrical contacts of back-contact solar cells.

The photovoltaic cell layer (also know as the active layer) of the module is made of an ever increasing variety of materials. Within the present invention, a solar cell layer 16 is meant to include any article which can convert light into electrical energy. Typical examples of the various forms of solar cells include, for example, single crystal silicon solar cells, polycrystal silicon solar cells, microcrystalline silicon solar cells, amorphous silicon based solar cells, copper indium (gallium) diselenide solar cells, cadmium telluride solar cells, compound semiconductor solar cells, dye sensitized solar cells, and the like. The most common types of solar cells include multi-crystalline solar cells, thin film solar cells, compound semiconductor solar cells and amorphous silicon solar cells due to relatively low cost manufacturing ease for large scale solar modules.

The front encapsulant layer 14 of the photovoltaic module is typically comprised of ethylene methacrylic acid and ethylene acrylic acid, ionomers derived therefrom, or combinations thereof. Such encapsulant layers may also be films or sheets comprising poly(vinyl butyral) (PVB), ethylene vinyl acetate (EVA), poly(vinyl acetal), polyurethane (PU), linear low density polyethylene, polyolefin block elastomers, ethylene acrylate ester copolymers, such as poly(ethylene-co-methyl acrylate) and poly(ethylene-co-butyl acrylate), ionomers, silicone polymers and epoxy resins. As used herein, the term “ionomer” means and denotes a thermoplastic resin containing both covalent and ionic bonds derived from ethylene/acrylic or methacrylic acid copolymers. In some embodiments, monomers formed by partial neutralization of ethylene-methacrylic acid copolymers or ethylene-acrylic acid copolymers with inorganic bases having cations of elements from Groups I, II, or III of the Periodic table, notably, sodium, zinc, aluminum, lithium, magnesium, and barium may be used. The term ionomer and the resins identified thereby are well known in the art, as evidenced by Richard W. Rees, “Ionic Bonding In Thermoplastic Resins”, DuPont Innovation, 1971, 2(2), pp. 1-4, and Richard W. Rees, “Physical 30 Properties And Structural Features Of Surlyn Ionomer Resins”, Polyelectrolytes, 1976, C, 177-197. Other suitable ionomers are further described in European patent no. EP1781735. The front encapsulant layer may further contain any additive known within the art. Such exemplary additives include, but are not limited to, plasticizers, processing aides, flow enhancing additives, lubricants, pigments, dyes, flame retardants, impact modifiers, nucleating agents to increase crystallinity, antiblocking agents such as silica, thermal stabilizers, hindered amine light stabilizers (HALS), UV absorbers, UV stabilizers, dispersants, surfactants, chelating agents, coupling agents, adhesives, primers, reinforcement additives such as glass fiber, fillers and the like. The front encapsulant layer typically has a thickness greater than or equal to 0.12 mm, and preferably greater than 0.25 mm. A preferred front encapsulant layer has a thickness in the range of 0.5 to 0.8 mm.

The photovoltaic module may further comprise one or more front sheet layers or film layers to serve as the light-transmitting substrate (also know as the incident layer). The light-transmitting layer may be comprised of glass or plastic sheets, such as, polycarbonate, acrylics, polyacrylate, cyclic polyolefins, such as ethylene norbornene polymers, metallocene-catalyzed polystyrene, polyamides, polyesters, fluoropolymers and the like and combinations thereof. Glass most commonly serves as the front sheet incident layer of the photovoltaic module. The term “glass” is meant to include not only window glass, plate glass, silicate glass, sheet glass, low iron glass, tempered glass, tempered CeO-free glass, and float glass, but also includes colored glass, specialty glass which includes ingredients to control, for example, solar heating, coated glass with, for example, sputtered metals, such as silver or indium tin oxide, for solar control purposes, E-glass, Toroglass, Solex® glass (a product of Solutia) and the like. The type of glass depends on the intended use.

A process of manufacturing the photovoltaic module with olefin-based elastomer containing layer/fluoropolymer film integrated back-sheet will now be disclosed. The photovoltaic module may be produced through a vacuum lamination process. For example, the photovoltaic module constructs described above may be laid up in a vacuum lamination press and laminated together under vacuum with heat and standard atmospheric or elevated pressure. In an exemplary process, a glass sheet, a front-sheet encapsulant layer, a photovoltaic cell layer, and an olefin-based elastomer containing layer adhered to a fluoropolymer film are laminated together under heat and pressure and a vacuum to remove air.

Preferably, the glass sheet has been washed and dried. In an exemplary procedure, the laminate assembly of the present invention is placed onto a platen of a vacuum laminator that has been heated to about 120° C. The laminator is closed and sealed and a vacuum is drawn in the chamber containing the laminate assembly. After an evacuation period of about 6 minutes, a silicon bladder is lowered over the laminate assembly to apply a positive pressure of about 1 atmosphere over a period of 1 to 2 minutes. The pressure is held for about 14 minutes, after which the pressure is released, the chamber is opened, and the laminate is removed from the chamber.

If desired, the edges of the photovoltaic module may be sealed to reduce moisture and air intrusion by any means known within the art. Such moisture and air intrusion may degrade the efficiency and lifetime of the photovoltaic module. General art edge seal materials include, but are not limited to, butyl rubber, polysulfide, silicone, polyurethane, polypropylene elastomers, polystyrene elastomers, block elastomers, styrene-ethylene-butylene-styrene (SEBS), and the like.

The described process should not be considered limiting. Essentially, any lamination process known within the art may be used to produce the photovoltaic modules with an integrated back-sheet of an olefin-based elastomer containing layer adhered to a fluoropolymer film, as disclosed herein.

While the presently disclosed invention has been illustrated and described with reference to preferred embodiments thereof, it will be appreciated by those skilled in the art that various changes and modifications can be made without departing from the scope of the present invention as defined in the appended claims.

### EXAMPLES

The following Examples are intended to be illustrative of the present invention, and are not intended in any way to limit the scope of the present invention described in the claims.

### Test Methods

### Damp Heat Exposure

The samples are placed into a dark chamber. The samples are mounted at approximately a 45 degree angle to the horizontal. The chamber is then brought to a temperature of 85° C. and relative humidity of 85%. These conditions are maintained for a specified number of hours. Samples are removed and tested after about 1000 hours of exposure. 1000 hours of exposure at 85° C. and 85% relative humidity is the required exposure in many photovoltaic module qualification standards.

### Peel Strength

Before and after the designated number of hours of damp heat exposure in the heat and humidity chamber, the laminated samples were removed for peel strength testing. Peel strength is a measure of adhesion between layers of the laminate. The peel strength was measured on an Instron mechanical tester with a 50 kilo loading cell according to ASTM D3167.

### Preparation of Test Mixtures of Olefin-Based Material

The ingredients listed in Table 1 were mixed in a tangential BR Banbury internal mixer made by Farrel Corporation of Ansonia, Conn. The non-polymer additives were charged into the mixing chamber of the Banbury mixer and mixed before the olefin-based copolymer and any thermoplastic polymer adhesive or rosin tackifier ingredients were introduced into the mixing chamber, in what is known as an upside down mixing procedure. The ingredient quantities listed in Table 1 are by weight parts relative to the parts olefin-based elastomer and other ingredients used in each of the examples.

The speed of the Banbury mixer's rotor was set to 75 rpm and cooling water at tap water temperature was circulated through a cooling jacket around the mixing chamber and through cooling passages in the rotor. The cooling water was circulated to control the heat generated by the mixing. The temperature of the mass being compounded was monitored during mixing. After all of the ingredients were charged into the mixing chamber and the temperature of the mass reached 82° C., a sweep of the mixing chamber was done to make sure that all ingredients were fully mixed into the compounded mass. When the temperature of the compounded mass reached 120° C., it was dumped from the mixing chamber into a metal mold pan.

The compounded mass in the mold pan was then sheeted by feeding the mixture into a 16 inch two roll rubber mill. Mixing of the compound was finished on the rubber mill by cross-cutting and cigar rolling the compounded mass. During sheeting, the mass cooled. The compounded mass for each of the samples weighed between 5 and 7 kg.

TABLE 1

| | Sample No. | | | | | |
|---|---|---|---|---|---|---|
| | 1 | 2 | 3 | 4 | 5 | 6 |
| Propylene-based | 45 | 30 | 45 | 45 | 45 | 45 |
| elastomer | | | | | | |
| Ethylene-based | 30 | 30 | 30 | 30 | 30 | 30 |
| elastomer | | | | | | |
| Ethylene alpha olefin | 25 | 10 | 15 | 20 | 15 | 20 |
| copolymer adhesive | | | | | | |
| Ethylene-acrylate | | 30 | | | | |
| copolymer | | | | | | |
| Acrylic hot melt | | | | | 10 | 5 |
| polymer adhesive | | | | | | |
| Tackifier | | | 10 | 5 | | |
| Calcium carbonate | 90 | 90 | 90 | 90 | 90 | 90 |
| particulates | | | | | | |
| Irganox 1010 | 1 | 1 | 1 | 1 | 1 | 1 |
| Tinuvin 1600 | 2.5 | 2.5 | 2.5 | 2.5 | 2.5 | 2.5 |
| Chimassorb 2020 | 1 | 1 | 1 | 1 | 1 | 1 |
| Titanium dioxide | 10 | 10 | 10 | 10 | 10 | 10 |
| Zinc Oxide | 5 | 5 | 5 | 5 | 5 | 5 |
| Stearic Acid | 1.5 | 1.5 | 1.5 | 1.5 | 1.5 | 1.5 |
| Carbowax 3350 | 1.5 | 1.5 | 1.5 | 1.5 | 1.5 | 1.5 |
| Z-6030 Silane | 2 | 2 | 2 | 2 | 2 | 2 |
| Luperox TBEC | 4 | 4 | 4 | 4 | 4 | 4 |
| SR 634 | 4 | 4 | 4 | 4 | 4 | 4 |
| Total Parts | 222.5 | 222.5 | 222.5 | 222.5 | 222.5 | 222.5 |

### Ingredients Glossary

| | |
|---|---|
| Propylene-based elastomer | Vistamaxx ™ 6202 propylene-based elastomer, with a |
| | density of 0.861 g/cm3, melt index of 7.4 g/10 min, and |
| | melt mass-flow rate (MFR)(230° C./2.16 Kg)(by ASTM |
| | D1238). Obtained from ExxonMobil Chemical |
| | Company, Houston, Texas, USA |
| Ethylene-based elastomer | Affinity ™ EG 8200 ethene-1-octene copolymer, with a |
| | density of 0.870 g/cm3, melt index of 5.0 g/10 min, and |
| | melting temperature of 145° F. Obtained from Dow |
| | Chemical Company, Midland, Michigan, USA |
| Ethylene alpha olefin | Affinity 1950 ™ ethene-1-octene copolymer plastomer, |
| copolymer adhesive | with a density of 0.874 g/cm3, and melting temperature |
| | of 158° F. Obtained from Dow Chemical Company, |
| | Midland, Michigan, USA |
| Ethylene-acrylate | Elvaloy ® PTW ethylene-acrylate copolymer |
| copolymer | thermoplastic resin from E.I. DuPont de Nemours and |
| | Company, Wilmington, Delaware, USA |
| Acrylic hot melt polymer | Euromelt 707 US synthetic hot melt polymer adhesive |
| adhesive | from Henkel Corporation of Dusseldorf, Germany |
| Tackifier | FloraRez 485 glycerol ester hydrogenated rosin tackifier |
| | from Florachem Corporation, Jacksonville, Florida, |
| | USA |
| Calcium carbonate | Precipitated Calcium Carbonate, with an average |
| particulates | particle size of 0.1 to 1 micron, obtained from Specialty |
| | Minerals, Bethlehem, PA |
| Irganox ® 1010 | [Benzenepropanoic acid, 3,5-bis(1,1-dimethyl)-4- |
| | hydroxy-2,2-bis[3-[3,5-bis(1,1-dimethylethyl)-4- |
| | hydroxyphenyl]-1-oxopropoxy]methyl]-1,3-propanediyl |
| | ester], BASF, Ludwigshafen, Germany |
| Tinuvin 1600 | Triazine derivative, BASF, Ludwigshafen, Germany |
| Chimassorb 2020 | 1,6-Hexanediamine,N,N′-bis(2,2,6,6-tetramethyl-4- |
| | piperidinyl)-polymer with 2,4,6-trichloro-1,3,5-triazine, |
| | reaction products with N-butyl-1-butanamide an N- |
| | butyl-2,2,6,6-tetramethyl-4-piperidinzmine, BASF, |
| | Ludwigshafen, Germany |
| Titanium dioxide | TiPure ® R-960 titanium dioxide from DuPont |
| Zinc Oxide | Zinc oxide, Horsehead Co., Monaca, Pennsylvania, USA |
| Stearic Acid | Stearic acid, PMC Biogenix Inc., Memphis, Tennessee, |
| | USA |
| Carbowax 3350 | Carbowax polyethylene glycol 3350 plasticizer from |
| | Dow Chemical Company of Midland, Michigan, USA |
| Z-6030 Silane | Methacryloxypropyl trimethoxysilane, Dow Corning |
| | Inc., Midland, Michigan, USA |
| Luperox TBEC | Carbonoperoxoic acid, OO-(1,1-dimethylethyl) O- |
| | (2-ethylhexyl) ester, Arkema Inc., King of Prussia, |
| | Pennsylvania 19406 |
| SR 634 | Metallic dimethacrylate, Sartomer Company, Inc., |
| | Exton, Pennsylvania, USA |

### Preparation and Testing of Back-Sheet Substrate Samples

The six sample mixtures as described above were melted and deposited on a polyvinyl fluoride film by a calendar coating process like that described with regard to FIG. 4. About 1 kg of each compounded sample mixture was placed between two 12 inch (30.5 cm diameter) chrome plated calendar rolls like the rolls 50 and 52 of FIG. 4 and melted. The rolls were rotating slowly in opposite directions as shown in FIG. 4. The rolls were spaced about 0.5 mm from each other and were heated to a surface temperature of approximately 60° C. A molten film of the olefin-based elastomer sample mixture was formed on the surface of the downwardly rotating roll. The molten film was transferred to the surface of an adjoining 12 inch (30.5 cm diameter chrome plated transfer roll like the roll 60 shown in FIG. 4, which was heated to maintain a roll surface temperature of approximately 700° C. The molten film was coated on to a 1.0 mil (25 microns) thick Tedlar® PVF film fed from a supply roll like the roll 12 shown in FIG. 4 to a nip formed between the transfer roll and a chrome plated back-up roll like the roll 61 shown in FIG. 4. The PVF film and olefin-based elastomer mixture coating layer passed through the nip where the back-up roll surface was maintained at approximately 100° C. A nip pressure of about 40 psi (276 kPa) was applied so as to adhere the olefin-based elastomer containing material layer to the PVF film. The PVF film with the adhered olefin-based elastomer containing layer was allowed to cool and the laminate was collected on a collection roll. The olefin-based elastomer containing material layer had a thickness of about 20 mils (0.5 mm). Six inch by six inch (15.2 cm by 15.2 cm) pre-form squares were subsequently die cut from the collected laminate so as to have a similar length and width as the mono-crystalline silicon solar cell.

The back-sheet substrate laminated samples were tested for initial peel strength and were subsequently subjected to the damp heat exposure test described above for 1000 hours and then tested again for peel strength between the olefin-based elastomer containing substrate and the PVF film. As show below in Table 2, the back-sheet substrate laminate samples had very high peel strength between the olefin-based elastomer containing substrate layer and Tedlar® PVF film both before and after 1000 hours of damp heat exposure. During initial peel strength testing and post damp heat peel strength testing, the olefin-based elastomer layer could not be separated from the Tedlar® PVF film. The PVF film tore before there was separation in the bond between the olefin-based elastomer slab and the PVF film.

TABLE 2

| | Example | | | | | |
|---|---|---|---|---|---|---|
| | 1 | 2 | 3 | 4 | 5 | 6 |
| | Slab Sample No. | | | | | |
| | 1 | 2 | 3 | 4 | 5 | 6 |
| Initial Peel Strength (g/in) | CNS | CNS | CNS | CNS | CNS | CNS |
| Peel Strength after 1000 hours | CNS | CNS | CNS | CNS | CNS | CNS |
| of Damp and Heat (g/in) | | | | | | |

CNS = could not separate propylene-based elastomer slab from PVF film before stretching elongation of propylene-based elastomer.

### Preparation and Testing of Mini Solar Modules

Six inch by six inch (15.2 cm by 15.2 cm) square mini solar modules were prepared from a layered structure of a 5 mm thick low iron glass sheet, followed by an 18 mil (0.46 mm) thick ethylene vinyl acetate encapsulant layer (Photocap® 15295 EVA sheet from Specialized Technology Resources, Inc. of Enfield, Conn.), followed by a mono-crystalline silicon solar cell with a back side contact made of aluminum and iso butyl rubber edge seals. In each example, one of the above described laminates of an approximately 20 mil (0.5 mm) thick olefin-based elastomer containing material layer adhered to a 1.0 mil (25 microns) thick Tedlar® PVF film was placed against the back side of a solar cell. The surface of the olefin-based elastomer containing material layer opposite the side adhered to the PVF film was placed directly against the back side aluminum contact of the mono-crystalline silicon solar cell. A 5 mil thick cell support release sheet made of Teflon® PTFE was place over the PVF film of the laminate, followed by a PTFE based heat bumper. Each cell had electrical connects to the outside at desired locations.

Each layered structure was placed into a lamination press having a platen heated to about 120-150° C. Each layered structure was allowed to rest on the platen for about 6 minutes to preheat the layered structure under vacuum. The lamination press was activated and the layered structure was pressed together using 1 atmosphere of pressure for 14 minutes to permit the olefin-based elastomer containing layer and front encapsulant to encapsulate silicon solar cell. The mini solar module was cooled and removed from the press.

The mini modules were tested prior to exposure to damp heat and after 1000 hours of damp heat exposure, as described above. The test was conducted according to Section 10.15 of IEC 61215. Maximum power (Pmax), short circuit current (Isc), open circuit voltage (Voc), series resistence (Rs), and shunt resistance (Rsh) were determined using a Spire SLP 4600 solar simulator. Prior to any testing, the instrument was calibrated using an NREL certified solar module (Kyocera 87 watt module). The thermal coefficient for 5″ JA Solar cells was used. The following standard conditions for single cell 5 inch modules were used:

Lamp intensity=100 mW/cm²

Fixed starting load voltage=7.2 V

Fixed voltage range=25 V

Fixed current range=6 A

The measured values for each mini module are report in Table 3 below.

TABLE 3

| | Example | | | | | |
|---|---|---|---|---|---|---|
| | 7 | 8 | 9 | 10 | 11 | 12 |
| | Back-sheet Laminate Sample No. | | | | | |
| | 1 | 2 | 3 | 4 | 5 | 6 |
| Pₘₐₓ (W) (initial) | 2.776 | 2.669 | 2.503 | 2.519 | 2.519 | 2.516 |
| Pₘₐₓ (W) (1000 hrs DH) | 2.786 | 2.661 | 2.547 | 2.583 | 2.569 | 2.566 |
| Isc (A) (initial) | 6.112 | 5.863 | 5.524 | 5.525 | 5.522 | 5.507 |
| Isc (A) (1000 hrs DH) | 6.051 | 5.803 | 5.438 | 5.484 | 5.504 | 5.445 |
| Voc (V) (initial) | 0.624 | 0.616 | 0.618 | 0.618 | 0.618 | 0.618 |
| Voc (V) (1000 hrs DH) | 0.628 | 0.621 | 0.625 | 0.625 | 0.625 | 0.626 |
| Rs (Ω) (initial) | 0.010 | 0.011 | 0.011 | 0.011 | 0.011 | 0.012 |
| Rs (Ω) (1000 hrs DH) | 0.012 | 0.012 | 0.011 | 0.009 | 0.010 | 0.011 |
| Rsh (Ω) (initial) | 26.810 | 56.369 | 63.023 | 51.068 | 49.781 | 57.640 |
| Rsh (Ω) | 31.321 | 55.396 | 31.726 | 35.456 | 48.379 | 32.350 |
| (1000 hrs DH) | | | | | | |

What is claimed is:

1. A process for forming a back-sheet for a photovoltaic module, comprising:
providing a fluoropolymer film;
providing a polymer melt comprising 10 to 85 weight percent olefin-based elastomer, 5 to 75 weight percent of inorganic particulates, and 5 to 80 weight percent of adhesive selected from thermoplastic polymer adhesives and tackifiers, based on the weight of the polymer melt, wherein said olefin-based elastomer is a copolymer comprised of at least 50 wt % of monomer units selected from ethylene and propylene monomer units copolymerized with one or more different C₂₋₂₀ alpha olefin monomer units, and said olefin-based elastomer has a melt index of less than 25 g/10 minutes measured according to ASTM D1238;
depositing the polymer melt directly on the fluoropolymer film and pressing said fluoropolymer film and polymer melt together and cooling the polymer melt to form a first polymer layer from the polymer melt, the first polymer layer having a thickness of at least 0.1 mm, wherein the peel strength between said fluoropolymer film and said first polymer layer is greater than 2 Newtons/cm after 1000 hours of exposure at 85° C. and 85% relative humidity.

2. The process of claim 1 wherein said first polymer layer comprises 20 to 75 weight percent of said olefin-based elastomer, 10 to 70 weight percent of inorganic particulates, and 10 to 60 weight percent of adhesive selected from thermoplastic polymer adhesives and rosin based tackifiers, based on the weight of the first polymer layer.

3. The process of claim 1 wherein said adhesive is a non-aromatic copolymer comprised of ethylene units copolymerized with one or more of the monomer units selected from C₃₋₂₀ alpha olefins, C₁₋₄ alkyl methacrylates, C₁₋₄ alkyl acrylates, methacrylic acid, acrylic acid, maleic anhydride, and glycidyl methacrylate, wherein the adhesive copolymer is comprised of at least 50 wt % ethylene derived units.

4. The process of claim 3 wherein said adhesive is a non-aromatic ethylene-based copolymer adhesive plastomer with a melt flow index of greater than 250.

5. The process of claim 1 wherein said inorganic particulates are selected from silica, silicates, calcium carbonate and titanium dioxide particles having an average particle diameter between and including any two of the following diameters: 0.1, 0.2, 15, 45, and 100 microns.

6. The process of claim 1 wherein said polymer melt is deposited on the fluoropolymer film by extruding the polymer melt as a layer directly onto the fluoropolymer film.

7. The process of claim 1 wherein said polymer melt is formed between heated calendar rolls and wherein said polymer melt is deposited from said heated calendar rolls directly onto said fluoropolymer film and passed through a nip to form a polymer layer adhered to said fluoropolymer film, said polymer layer having a thickness of at least 0.1 mm, and wherein the peel strength between said fluoropolymer film and said first polymer layer is greater than 8 Newtons/cm after 1000 hours of exposure at 85° C. and 85% relative humidity, where peel strength is measured according to ASTM D3167.

8. A process for forming a photovoltaic module, comprising:
providing a fluoropolymer film;
providing a polymer melt comprising 10 to 85 weight percent olefin-based elastomer, 5 to 75 weight percent of inorganic particulates, and 5 to 80 weight percent of adhesive selected from thermoplastic polymer adhesives and tackifiers, based on the weight of the polymer melt, wherein said olefin-based elastomer is a copolymer comprised of at least 50 weight percent of monomer units selected from ethylene and propylene monomer units copolymerized with one or more different C₂₋₂₀ alpha olefin monomer units, and said olefin-based elastomer has a melt index of less than 25 g/10 minutes measured according to ASTM D1238;
depositing the polymer melt directly on the fluoropolymer film and pressing said fluoropolymer film and polymer melt together and cooling the polymer melt to form a first polymer layer from the polymer melt, the first polymer layer having a thickness of at least 0.1 mm and having a first side adhered directly to the fluoropolymer film and an opposite second side, wherein the peel strength between said fluoropolymer film and said first polymer layer is greater than 2 Newtons/cm after 1000 hours of exposure at 85° C. and 85% relative humidity;
providing a plurality of solar cells each having a front sunlight receiving side and an opposite rear side; and
pressing the second side of said first polymer layer directly against the rear side of said solar cells and heating said first polymer layer to adhere the second side of the first polymer layer to the rear side of said solar cells.

9. The process of claim 8 wherein said adhesive is a non-aromatic copolymer comprised of ethylene units copolymerized with one or more of the monomer units selected from C₃₋₂₀ alpha olefins, C₁₋₄ alkyl methacrylates, C₁₋₄ alkyl acrylates, methacrylic acid, acrylic acid, maleic anhydride, and glycidyl methacrylate, wherein the adhesive copolymer is comprised of at least 50 wt % ethylene derived units.

10. The process of claim 8 wherein said first polymer layer comprises 10 to 70 weight percent of inorganic particulates, based on the weight of the first polymer layer, and wherein the inorganic particulates are selected from silica, silicates, calcium carbonate and titanium dioxide having an average particle diameter between and including any two of the following diameters: 0.1, 0.2, 15, 45 microns.

11. An integrated back-sheet for a photovoltaic module, comprising:
a fluoropolymer film having opposite first and second sides;
a polymer layer adhered directly the first side of said fluoropolymer film, said polymer layer comprising 10 to 85 weight percent olefin-based elastomer, 5 to 75 weight percent of inorganic particulates, and 5 to 80 weight percent of adhesive selected from thermoplastic polymer adhesives and tackifiers, based on the weight of the polymer layer, wherein said olefin-based elastomer is a copolymer comprised of at least 50 wt % of monomer units selected from ethylene and propylene monomer units copolymerized with one or more different C₂₋₂₀ alpha olefin monomer units, and said olefin-based elastomer has a melt index of less than 25 g/10 minutes measured according to ASTM D1238, said polymer layer having a thickness of at least 0.25 mm, and wherein the peel strength between said fluoropolymer film and said polymer layer is greater than 2 Newtons/cm after 1000 hours of exposure at 85° C. and 85% relative humidity, where peel strength is measured according to ASTM D3167.

12. The integrated back-sheet of claim 11 wherein said fluoropolymer film consists essentially of a film selected from polyvinyl fluoride homopolymer and copolymer films and polyvinylidene fluoride homopolymer and copolymer films.

13. A photovoltaic module comprising:
a plurality of solar cells having a front light receiving side and an opposite rear side;
a polymer layer having opposite first and second sides, the first side of the polymer layer being adhered directly to the rear side of said plurality of solar cells, said polymer layer comprising 10 to 85 weight percent olefin-based elastomer, 5 to 75 weight percent of inorganic particulates, and 5 to 80 weight percent of adhesive selected from thermoplastic polymer adhesives and tackifiers, based on the weight of the polymer layer, wherein said olefin-based elastomer is a copolymer comprised of at least 50 wt % of monomer units selected from ethylene and propylene monomer units copolymerized with one or more different C₂₋₂₀ alpha olefin monomer units, and said olefin-based elastomer has a melt index of less than 25 g/10 minutes measured according to ASTM D1238; and
a fluoropolymer film adhered directly to the second side of the polymer layer, said fluoropolymer film forming an exposed surface of the photovoltaic module.

14. The photovoltaic module of claim 13 wherein said polymer layer comprises 20 to 75 weight percent olefin-based elastomer, 10 to 70 weight percent of inorganic particulates, and 10 to 60 weight percent of adhesive selected from thermoplastic polymer adhesives and rosin based tackifiers, based on the weight of the polymer layer.

15. The photovoltaic module of claim 13 wherein said adhesive is a non-aromatic copolymer comprised of ethylene units copolymerized with one or more of the monomer units selected from C₃₋₂₀ alpha olefins, C₁₋₄ alkyl methacrylates, C₁₋₄ alkyl acrylates, methacrylic acid, acrylic acid, maleic anhydride, and glycidyl methacrylate, wherein the adhesive copolymer is comprised of at least 50 wt % ethylene derived units.

16. The process of claim 15 wherein said adhesive is a non-aromatic ethylene-based copolymer adhesive plastomer with a melt flow index of greater than 250.

17. The photovoltaic module of claim 13 wherein said polymer layer comprises 25 to 60 weight percent of inorganic particulates based on the weight of the polymer layer, said inorganic particulates selected from silica, silicates, calcium carbonate and titanium dioxide, and said inorganic particulates having an average particle diameter between and including any two of the following diameters: 0.1, 0.2, 15, 45 microns.

18. The photovoltaic module of claim 13 wherein said polymer layer has a thickness in the range of 0.25 to 0.80 mm, and the peel strength between said fluoropolymer film and said first polymer layer is greater than 8 Newtons/cm after 1000 hours of exposure at 85° C. and 85% relative humidity, where peel strength is measured according to ASTM D3167.

19. The photovoltaic module of claim 13 wherein a metal layer from the group of metal foils, sputtered metal layers, and metal oxide layers is incorporated into said polymer layer.
